(19) United States
(12) Patent Application Publication
(10) Pub. No.: US 2024/0081135 A1
(43) Pub. Date: Mar. 7, 2024

(54) Rigid Sapphire Based Direct Patterning Deposition Mask

(71) Applicant: eMagin Corporation, Hopewell Junction, NY (US)

(72) Inventors: Amalkumar P. GHOSH, Hopewell Junction, NY (US); Howard LIN, Hopewell Junction, NY (US); Fridrich VAZAN, Pittsford, NY (US); Ilyas I. KHAYRULLIN, Hopewell Junction, NY (US); Fangchao ZHAO, Hopewell Junction, NY (US); Kerry TICE, Hopewell Junction, NY (US); Timothy CONSIDINE, Hopewell Junction, NY (US); Laurie SZIKLAS, Hopewell Junction, NY (US)

(21) Appl. No.: 18/236,243

(22) Filed: Aug. 21, 2023

Related U.S. Application Data
(60) Provisional application No. 63/403,964, filed on Sep. 6, 2022.

(51) Int. Cl. H10K 71/16

(52) U.S. Cl. CPC H10K 71/166

(57) ABSTRACT

A direct patterning deposition mask for OLED deposition is provided where the mask includes a sapphire substrate; and a Silicon Nitride (SiN) membrane. The sapphire substrate thickness may be between 0.7 and 2 mm. The sapphire substrate may have a diameter in the range of 200 mm diameter to 300 mm diameter. Warpage of the substrate is preferably less than <10 um.

### CROSS-REFERENCE TO RELATED APPLICATION

This application claims priority to U.S. Provisional Patent Application No. 63/403,964 filed Sep. 6, 2022, entitled Rigid Sapphire Based Direct Patterning Deposition Mask, pending.

### BACKGROUND OF THE INVENTION

The present application is directed to direct patterning deposition (dPd). More particularly, the present invention is directed to dPd technology in displays.

Shadow-mask-based deposition is a process by which a layer of material is deposited onto the surface of a substrate such that the desired pattern of the layer is defined during the deposition process itself. This is deposition technique is sometimes referred to as “direct patterning.”

In a typical shadow-mask deposition process, the desired material is vaporized at a source that is located at a distance from the substrate, with a shadow mask positioned between them. As the vaporized atoms of the material travel toward the substrate, they pass through a set of through-holes in the shadow mask, which is positioned just in front of the substrate surface. The through-holes (i.e., apertures) are arranged in the desired pattern for the material on the substrate. As a result, the shadow mask blocks passage of all vaporized atoms except those that pass through the through-holes, which deposit on the substrate surface in the desired pattern. Shadow-mask-based deposition is analogous to silk-screening techniques used to form patterns (e.g., uniform numbers, etc.) on articles of clothing or stenciling used to develop artwork.

Shadow-mask-based deposition has been used for many years in the integrated-circuit (IC) industry to deposit patterns of material on substrates, due, in part, to the fact that it avoids the need for patterning a material layer after it has been deposited. As a result, its use eliminates the need to expose the deposited material to harsh chemicals (e.g., acid-based etchants, caustic photolithography development chemicals, etc.) to pattern it. In addition, shadow-mask-based deposition requires less handling and processing of the substrate, thereby reducing the risk of substrate breakage and increasing fabrication yield. Furthermore, many materials, such as organic materials, cannot be subjected to photolithographic chemicals without damaging them, which makes depositing such materials by shadow mask a necessity.

A high quality dPd mask is a key fixture for dPd manufacturing, particularly for OLED microdisplays.

By using direct patterning of OLED with stencil lithography, high-efficiency, high-resolution OLED microdisplays can be fabricated. Color emitter deposition for OLED uses a shadow mask that can have nm scale features. The shadow masks have precision and accuracy to match the underlying transistor of the microdisplay and create color emitters at higher resolution.

As can be seen in FIG. 1, a flat substrate, such as a silicon wafer, as known, was used to build a shadow mask. A thin film, such as silicon nitride, is deposited on both sides of the substrate using chemical vapor deposition (CVD). This silicon nitride layer may function as an etch barrier on one side and a free-standing membrane on the other side. Silicon oxide, aluminum oxide, or other thin film materials also have been used instead of the silicon nitride. One side of the thin film is etched to expose the substrate for a subsequent through substrate etch process. For example, the silicon nitride may be patterned using photolithography and dry etched to remove silicon nitride. The other side of the thin film is patterned using lithography and etched to create the desired shadow mask pattern. Again, this may use photolithography with dry etch. Of course, other patterning methods may be used. U.S. Pat. No. 9,385,323 (Chan et al.) describes this prior art process in detail.

The through substrate etch freely suspends the thin film, which enables the film to be used as a shadow mask. The substrate may be etched using, for example, potassium hydroxide.

Patterned evaporation may be performed through the shadow mask. A microdisplay substrate is placed near or in contact with the shadow mask. The setup can be brought into a deposition system to evaporate material. After evaporation, there will be a patterned material on the substrate. This is illustrated in FIG. 2.

There are two main challenges with dPd technology. First, the dPd mask must be manufactured as flat as possible. Conventionally, a silicon (Si) wafer has been used as the frame material. See FIG. 3. A SiN (silicon nitride) film is deposited, then a high-resolution pattern is made. See FIG. 4 which depicts a typical 1 μm SiN mask for a dPd process. However, due to the limited rigidity of the Si wafer (up to 35 μm warpage for 0.7 mm Si is typical in the integrated circuit (IC) industry), an appreciable warpage and bow is left after dPd mask fabrication. As a result, the Si-based dPd mask warpage can be as high as 30-40 μm (see FIG. 5 which depicts an example of dPd mask warpage measured across an 8-inch wafer, with a SiN membrane on top of an Si frame). Table 1 below shows an example of dPd mask warpage across an 8 inch wafer, with a Silicon Nitride membrane on top of an Si frame at points 1-4 of FIG. 5:

TABLE 1

| POSITION | MASK 1 (RG) μm | MASK 2 (B) μm |
|---|---|---|
| 1 | 38.8 | 30.4 |
| 2 | 39.7 | 32 |
| 3 | 36.7 | 30.67 |
| 4 | 38.8 | 33 |

This high mask warpage can generate big gaps between the mask and wafer during organic deposition and result in unwanted feathering in the lateral deposition. Deposited material tends to spread laterally after passing through the shadow mask—referred to as “feathering.” Feathering increases with the magnitude of the separation between the substrate and the shadow mask. To mitigate feathering, this separation is kept as small as possible without compromising the integrity of the chucks that hold the substrate and shadow mask. Still further, any non-uniformity in this separation across the deposition area will give rise to variations on the amount of feathering. Such non-uniformity can arise from, for example, a lack of parallelism between the substrate and shadow mask, bowing or sagging of one or both of the substrate and shadow mask, and the like. Furthermore, a shadow mask must be supported only at its perimeter to avoid blocking the passage of vaporized atoms to the through-hole pattern. As a result, the center of the shadow mask can sag due to gravity, which further exacerbates feathering issues. See FIG. 6 which depicts an example of feathering distance calculated for two deposition angles as the wafer-to-mask gap varies from 1 to 10 micrometers.

A second challenge is the related to the manufacturability of the substrate. In order to integrate both the SiN membrane and the rigid substrate together for making a dPd mask, a suitable process has to be designed for substrate etch, chemical compatibility, etc. Substrate properties and process integration have to be considered.

### SUMMARY OF THE INVENTION

The present invention is directed to a direct patterning deposition mask for OLED deposition, where the mask includes a sapphire substrate, and a silicon nitride (SiN) membrane. The sapphire substrate thickness may be, for example, between 0.7 and 2 mm. The sapphire substrate (wafer) diameter includes may be, for example, 200 mm diameter or 300 mm diameter. A sapphire wafer patterning process is preferably compatible with the SiN membrane process. Warpage of the substrate may be limited to, for example, less than 10 um. The mask improves OLED pixel deposition feathering and OLED performance.

A process for etching a sapphire substrate is also provided, which includes at least two of the steps of mechanical drilling, wet etching; dry etching, and laser-induced etching, plus wet etching.

### BRIEF DESCRIPTION OF THE DRAWINGS

FIG. 1 is an example of major fabrication steps for a prior art silicon nitride membrane, including (1) silicon wafer; (2) silicon nitride deposition; (3) backside lithography; (4) front side lithography; and (5) through wafer etch from back-side.

FIG. 2 is a simplified view illustrating deposition through a shadow mask.

FIG. 3 is a top, plan view of a typical prior art 1μ SiN mask for a dPd process.

FIG. 4 is a simplified view illustrating a prior art example of a SiN mask cross section.

FIG. 5 is a simplified view of an example of dPd mass warpage measured across an eight inch wafer, with a SiN membrane on top of a Si frame, as shown in Table 1 (above).

FIG. 6 is a graphical depiction of an example of feathering distance calculated for two deposition angles as a wafer-to-mask gap varies from 1 to 10 μm.

FIG. 7 is a simplified view major manufacturing steps for silicon nitride membrane, including (1) sapphire wafer; (2) silicon nitride deposition; (3) backside lithography; (4) front side lithography; and (5) through sapphire wafer wet etch from back-side.

FIG. 8 depicts the simplified steps for an example of a process for making a sapphire based SiN mask.

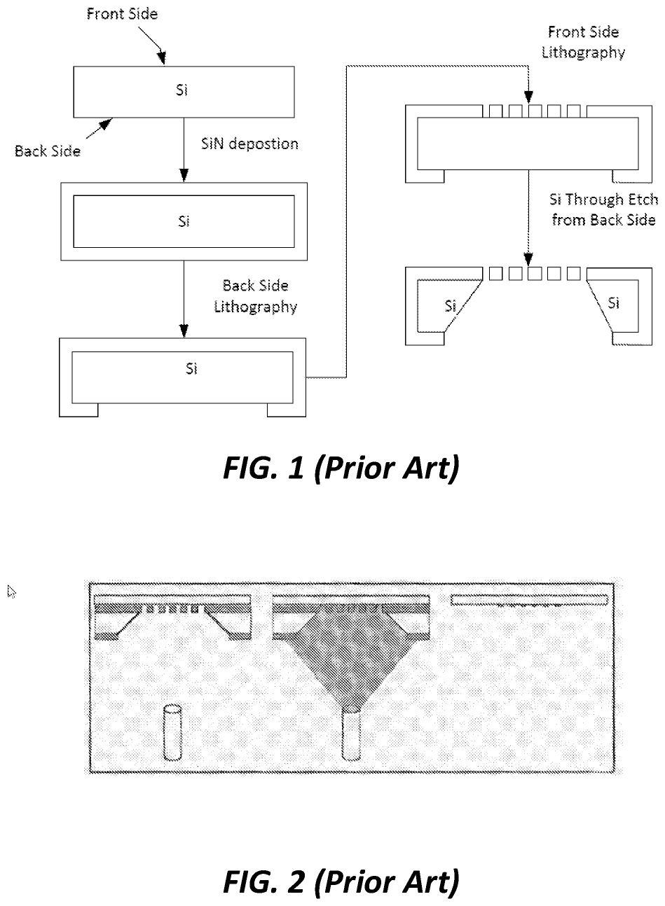

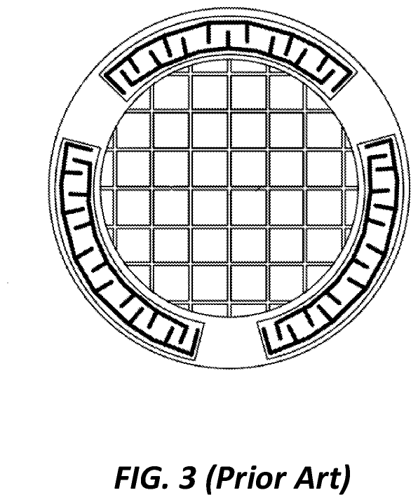

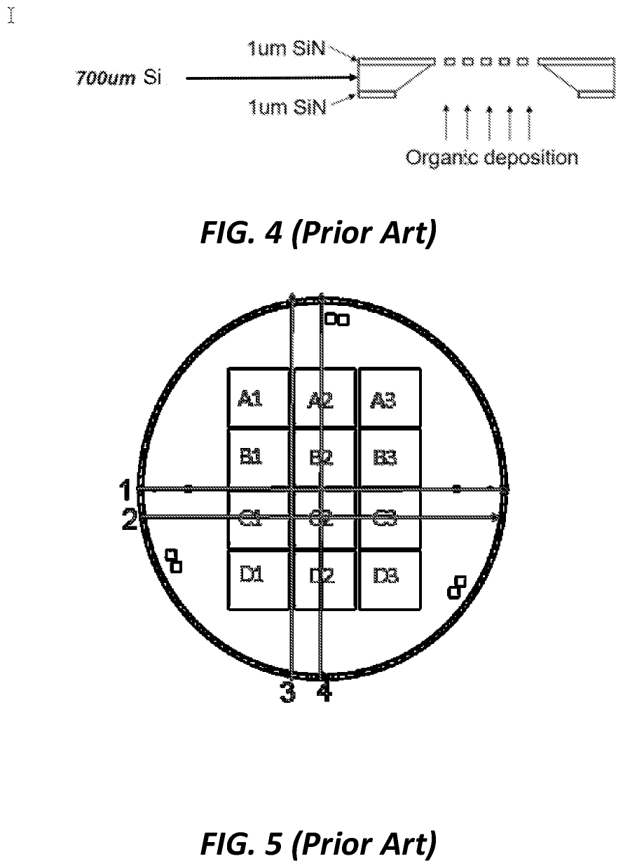

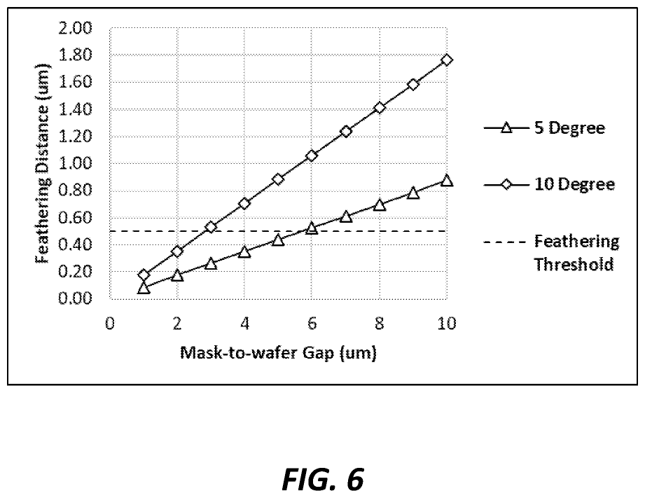

### DETAILED DESCRIPTION

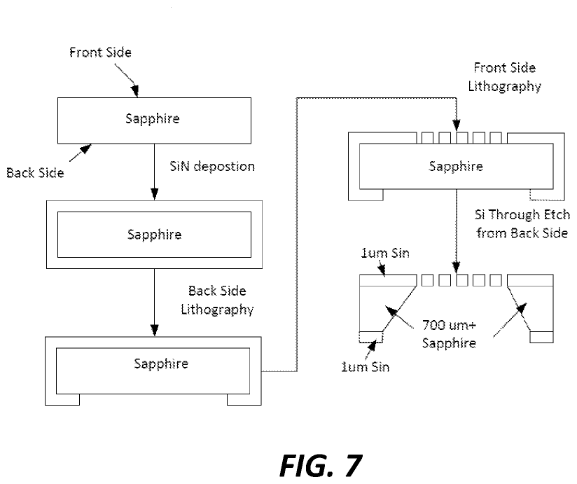

The present invention is directed to a direct patterning deposition mask for OLED deposition. The mask includes a sapphire substrate and a Silicon Nitride (SiN) membrane. In order to reduce mask warpage, the present invention is directed to sapphire as the base material for SiN deposition and patterning. See FIG. 7 which depicts a method for manufacturing a sapphire wafer as a dPd mask base material. Sapphire wafers with very good rigidity have been widely used in the LED industry. Sapphire wafers have a Young's Modulus that is approximately two times as high as Si wafers (as shown in Table 2 below which shows sapphire and silicon properties as comparted to silicon nitride, diamond and invar).

TABLE 2

| | Young's Modulus (Gpa) | CTE(ppm/C.) |
|---|---|---|
| SIN | 290 | 3.3 |
| Si | 168.9 | 2.6-3.3 |
| Sapphire | 340-400 | 5.5 |
| Diamond | 1220 | 0.8 |
| Invar | 137 | 1.2 |
| (Fe64Ni36) | | |

1.3 mm thick sapphire warpage can be controlled to <8 μm based on an investigation shown in Table 3 (below) which depicts examples of silicon wafer warpage as compared to Table 4 (below) which depicts sapphire wafer warpage.

TABLE 3

| | Specification | MEAN | S.D. | N | MIN. | MAX. |
|---|---|---|---|---|---|---|
| BOW (μm) | <35 | 1.009 | 0.649 | 125 | −1.028 | 2.663 |
| WARP (μm) | <35 | 6.150 | 1.734 | 125 | 3.070 | 14.970 |

TABLE 4
8 INCH DIAMETER SAPPHIRE WAFER; 1.3t SSP

| | Diameter | Thickness | BOW | WARP | |
|---|---|---|---|---|---|
| | 200 +/− 0.25 | 1.3 +/− 0.025 | 0 +/− 6 | </=5 | PARTICLE |
| | mm diameter | mm | μm | μm | — |
| 1 | 199.91 | 1.307 | −3.40 | 4.32 | 91 |
| 2 | 199.91 | 1.306 | −3.13 | 5.45 | 122 |
| 3 | 199.91 | 1.308 | −3.79 | 6.55 | 187 |
| 4 | 199.91 | 1.310 | −4.03 | 6.01 | 70 |
| 5 | 199.91 | 1.305 | −4.90 | 7.10 | 59 |
| 6 | 199.91 | 1.307 | 0.84 | 2.61 | 1.38 |

However, for sapphire, typical dry etch only gives a nm(s)/min etch rate. Essentially, this means that a 2-3 week period is needed to finish one wafer's etch, which is not practical. Instead, newly developed high temperature wet etch can give um(s)/min etch rate, which reduces the wafer's etch time to 1 day or less.

In the past, a 190° C. limit has existed for etching baths. Sapphire etching rates increase geometrically with temperature. An etching bath that achieves a 300-degree temperature is desirable.

During wet etching at relatively high temperatures, such as 300 degrees, wafers masked with SiN are placed in a high-temperature process tanks with a mixture of etching and buffering agents. Before submersion, a plasma-enhanced chemical vapor process adds a silicon dioxide mask onto the sapphire substrate, and lithography exposes the required pattern. The mixture is at temperatures, for example, 260 to 300° C.

White Knight's Accubath™ quartz tanks and specially-designed automated stations that make sapphire wet etching safe, reliable, and suitable for high volume manufacturing. See https://wkfluidhandling.com/resources/sapphire-etching/.

The high temperature wet etching process holds the advantage over dry etching in terms of speed, cost, and scalability.

In the present invention, the sapphire substrate thickness is preferably between 0.7 and 2 mm. The sapphire substrate preferably has a diameter in the range of 200 mm diameter to 300 mm diameter. Warpage of the substrate is preferably <10 um.

In accordance with another exemplary embodiment of the present invention, selective laser-induced etching (SLE), as known, may be used in a two-step process. In a first step, sapphire is modified internally by laser radiation to increase chemical etchability. To prevent the formation of cracks in the brittle material, short pulse duration (fs-ps) and a small focal volume (a few μm³) are used. During the laser modification, crystallinity of sapphire is downgraded, e.g., from crystalline to amorphous. In a second step, the modified sapphire is removed by wet etching, such as with a potassium hydroxide (KOH) etch.

In the first step, ultra-short pulsed laser radiation is focused into a volume of substrate. The pulse energy is absorbed only in the focus volume based on a multiphoton process. The process modifies the substrate without cracking it, thereby changing its chemical properties. This way, the material can be selectively chemically etched.

Additionally, a combination of several etch methods may be used with respect to sapphire etching. For example, mechanical drilling, laser treatment, KOH etching, high temperature wet etch (described above), Cl₂—based inductively coupled plasma (ICP) etching, and Cl₂, BCl₃, ICP, reactive ion etching (RIE), 20C etching. Table 5 below shows a comparison of several sapphire thin down and etch methods.

| | | | Time to Etch 500 μm | |
|---|---|---|---|---|
| Etch Method | Etch Rate | | thickness | |
| Mechanical Drilling | High | | ~minutes to tens of | |
| | | | minutes | |
| Laser Treatment, then | 10 | μm/minute | 50 | min. |
| 30 wt % KOH (Ultrasonic | | | | |
| bath, 80 C.) | | | | |
| High Temperature Wet | >1 | μm/minute | 8.3 | hr |
| Etch; sulfuric and | | | | |
| phosphoric acids, 260- | | | | |
| 300 C. | | | | |
| Cl₂ + ICP | 0.1 | μm/minute | 83.3 hr | (3.5 days) |
| Cl₂, BCl₃, ICP + RIE, 20 C. | 0.43 | μm/minute | 192 hr | (8 days) |

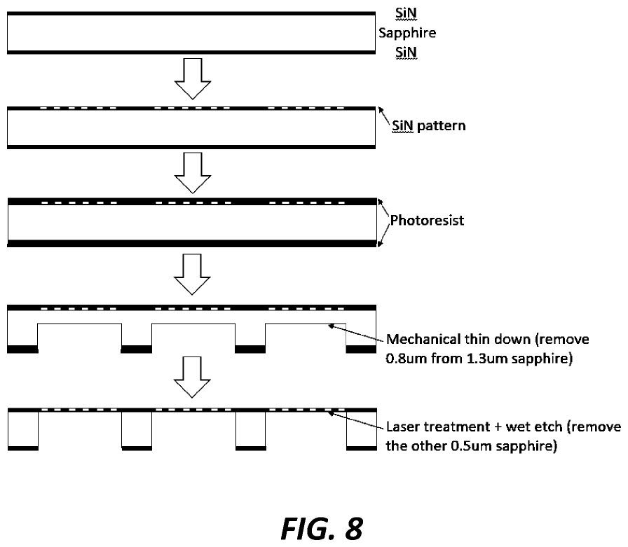

FIG. 8 depicts an example of a process for making a sapphire based SiN mask. The process begins with a sapphire substrate having SiN membrane. A pattern is placed on the SiN membrane by, one or more of mechanical drilling, wet etching, dry etching, selective and laser-induced etching plus wet etch. Photoresist is applied to the substrate, removal of sapphire (mechanical think down), of the surface of the membrane opposite the pattern, for example, removal of 0.8 to 1.3 mm of sapphire, then laser treatment plus wet etch to remove a remaining 0.5 mm of sapphire.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. A direct patterning deposition mask for OLED deposition, the mask comprising:
(a) a sapphire substrate; and
(b) Silicon Nitride (SiN) membrane.

2. The direct patterning deposition mask of claim 1, wherein the sapphire substrate thickness is between 0.7 and 2 mm.

3. The direct patterning deposition mask of claim 1, wherein the sapphire substrate has a diameter in the range of 200 mm diameter to 300 mm diameter.

4. The direct patterning deposition mask of claim 1, wherein warpage of the substrate is <10 um.

5. A process for etching a sapphire substrate, comprising at least two of the steps of:
(a) mechanical drilling;
(b) wet etching;
(c) dry etching; and
(d) laser-induced etching, plus wet etching.
